(19) United States
(12) Patent Application Publication
(10) Pub. No.: US 2026/0053262 A1
(43) Pub. Date: Feb. 26, 2026

(54) SUBSTRATE PROCESSING BRUSH AND SUBSTRATE PROCESSING APPARATUS COMPRISING THE SAME

(71) Applicants: SEMES CO., LTD., Cheonan-si (KR); Samsung Electronics Co., Ltd., Suwon-si (KR)

(72) Inventors: Young Jin KIM, Cheonan-si (KR); Tae Ho KANG, Suwon-si (KR); Cheol Hwan JEONG, Pyeongtaek-si (KR); Gu Yeol AN, Busan (KR); Seong Hyun YUN, Cheonan-si (KR); Hyun Woo LIM, Suwon-si (KR); You Hwan KIM, Suwon-si (KR); Tae Soon KANG, Suwon-si (KR); Kyoung Seob KIM, Suwon-si (KR); Ji Hye NOH, Suwon-si (KR); Hyoung Geun PARK, Suwon-si (KR); Jong Hyun CHUNG, Suwon-si (KR)

(21) Appl. No.: 19/185,128

(22) Filed: Apr. 21, 2025

(30) Foreign Application Priority Data
Aug. 22, 2024 (KR) 10-2024-0112513

(51) Int. Cl. A46B 15/00; A46B 13/00; A46B 13/02; B24B 29/00; B24D 13/14; H01L 21/67

(52) U.S. Cl. CPC A46B 15/0055; A46B 13/008; A46B 13/02; B24B 29/005; B24D 13/145; A46B 2200/3073; A46B 2200/3086; H01L 21/67046

(57) ABSTRACT

A substrate processing brush according to some embodiments of the present disclosure is provided. The substrate processing brush includes a holder; a substrate processing pad detachably disposed in the holder, processing the substrate; and a substrate processing sweeper connected to the holder, processing the substrate together with the substrate processing pad, wherein a first portion of the substrate processing pad is disposed inside the holder, and a second portion of the substrate processing pad is protruded to the outside of the holder by passing through one surface of the holder, and the substrate processing sweeper is connected to one surface of the holder so that it is to be adjacent to the second portion of the substrate processing pad protruded to the outside of the holder, and is extended from one surface of the holder.

### CROSS-REFERENCE TO RELATED APPLICATION

This application claims priority from Korean Patent Application No. 10-2024-0112513 filed on Aug. 22, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to a substrate processing brush and a substrate processing apparatus comprising the same.

### Description of the Related Art

A semiconductor fabricating process or a display fabricating process includes a substrate processing process of processing a substrate such as a wafer or a glass substrate. In the substrate processing process, one surface of the substrate may be processed using a substrate processing brush. For example, in the substrate processing process, one surface of the substrate is cleaned or polished using the substrate processing brush.

In the substrate processing brush of the related art, a worker connects a substrate processing pad of processing one surface of a substrate in contact with one surface of the substrate to a lower portion of a holder by covering the holder with the substrate processing pad. In the substrate processing brush of this configuration, the substrate processing pad may be contaminated by the worker, and the substrate may be contaminated by the contaminated substrate processing pad. In addition, since the connection of the substrate processing pad to the holder is made manually by the worker, horizontality of the substrate processing pad connected to the holder is not good. For this reason, processing of one surface of the substrate by the substrate processing pad is not uniformly performed for all of one surface of the substrate, and the substrate processing pad is partially worn away without being uniformly worn away as a whole.

Meanwhile, in order to remove particles generated when processing the substrate with the substrate processing pad, the substrate processing brush may include a substrate processing sweeper in addition to the substrate processing pad.

In the substrate processing brush of the related art, which includes a substrate processing pad and a substrate processing sweeper, the substrate processing pad and the substrate processing sweeper are attached to the holder by an adhesive. In this way, since the substrate processing pad and the substrate processing sweeper are attached to the holder by the adhesive, the substrate is contaminated by the adhesive. This adhesive is exposed to chemicals in a semiconductor fabricating process or a display fabricating process, which is performed using chemicals, resulting in weakened adhesive strength to cause detachment of the substrate processing pad and making chemical reaction by-products different from the chemicals to cause contamination of the substrate. In addition, for processing of the substrate, the substrate processing pad that is worn away due to direct contact with the substrate cannot be separately replaced, whereby maintenance costs are high.

### SUMMARY

An object of the present disclosure is to provide a substrate processing brush and a substrate processing apparatus comprising the same, in which maintenance costs may be reduced by preventing a substrate from being contaminated and separately replacing a substrate processing pad.

The objects of the present disclosure are not limited to those mentioned above and additional objects of the present disclosure, which are not mentioned herein, will be clearly understood by those skilled in the art from the following description of the present disclosure.

A substrate processing brush according to some embodiments of the present disclosure is provided. The substrate processing brush includes a holder; a substrate processing pad detachably disposed in the holder, processing the substrate; and a substrate processing sweeper connected to the holder, processing the substrate together with the substrate processing pad, wherein a first portion of the substrate processing pad is disposed inside the holder, and a second portion of the substrate processing pad is protruded to the outside of the holder by passing through one surface of the holder, and the substrate processing sweeper is connected to one surface of the holder so that it is to be adjacent to the second portion of the substrate processing pad protruded to the outside of the holder, and is extended from one surface of the holder.

A substrate processing brush according to some embodiments of the present disclosure is provided. The substrate processing brush comprises a holder; a substrate processing pad detachably disposed in the holder, processing the substrate; a substrate processing sweeper connected to the holder, processing the substrate together with the substrate processing pad; and a pressing member disposed inside the holder to bring the substrate processing pad into close contact with the holder; and a shaft connection member disposed inside the holder between an upper surface of the holder and the pressing member and connected to a brush rotation shaft passing through the upper surface of the holder, wherein the substrate processing pad includes a pad body portion disposed inside the holder, and a pad protrusion portion having an upper portion connected to the pad body portion, protruded downward as much as a protruded length from a lower surface of the holder to the outside of the holder by passing through the lower surface of the holder, and the substrate processing sweeper has an upper portion connected to the lower surface of the holder so that it is to be adjacent to the pad protrusion portion, and is extended downward as much as an extended length smaller than the protruded length from the lower surface of the holder.

A substrate processing apparatus according to some embodiments of the present disclosure is provided. The apparatus comprises a processing container in which a processing space is formed; a support unit supporting and rotating a substrate in the processing space; and a brush unit including a substrate processing brush that processes the substrate supported by the support unit, wherein the substrate processing brush includes: a holder; a substrate processing pad detachably disposed in the holder, processing the substrate; and a substrate processing sweeper connected to the holder, processing the substrate together with the substrate processing pad, a first portion of the substrate processing pad is disposed inside the holder, and a second portion of the substrate processing pad is protruded to the outside of the holder by passing through one surface of the holder, and the substrate processing sweeper is connected to one surface of the holder so that it is to be adjacent to the second portion of the substrate processing pad protruded to the outside of the holder, and is extended from one surface of the holder.

Specific details of other embodiments are included in the detailed description and drawings.

### BRIEF DESCRIPTION OF THE DRAWINGS

The above and other aspects and features of the present disclosure will become more apparent by describing in detail embodiments thereof with reference to the attached drawings, in which:

FIG. 1 is a view illustrating a substrate processing brush according to some embodiments of the present disclosure.

FIG. 2 is an exploded view illustrating the substrate processing brush of FIG. 1.

FIG. 3 is a cross-sectional view taken along line I-I′ of FIG. 1.

FIG. 4 is a cross-sectional view taken along line II-II′ of FIG. 1.

FIG. 5 is a bottom view illustrating the holder of the substrate processing brush of FIG. 1.

FIG. 6 is a bottom view illustrating a substrate processing pad of the substrate processing brush of FIG. 1.

FIG. 7 is a bottom view illustrating a pressing member of the substrate processing brush of FIG. 1.

FIG. 8 is a view illustrating that one surface of the substrate is processed by the substrate processing brush of FIG. 1.

FIG. 9 is a view illustrating that the substrate processing pad of the substrate processing brush FIG. 1 is worn away, so that the protruded length of the substrate processing pad is the same as or smaller than the extended length of the substrate processing sweeper.

FIGS. 10 and 11 are views illustrating replacement of a substrate processing pad of the substrate processing brush of FIG. 1.

FIG. 12 is a view illustrating a substrate processing apparatus according to some embodiments of the present disclosure.

FIG. 13 is a view illustrating a substrate processing facility to which a substrate processing apparatus according to some embodiments of the present disclosure may be applied.

FIG. 14 is a cross-sectional view illustrating the substrate processing facility of FIG. 13.

### DETAILED DESCRIPTION OF THE DISCLOSURE

Although terms such as first, second, upper, and lower are used herein to describe various elements or components, it is obvious that these elements or components are not limited by the terms. Rather, the terms are merely used herein to distinguish one element or component from another element or component. Therefore, it is obvious that a first element or component as mentioned below may also be a second element or component within the technical spirit of the present disclosure. Further, it is obvious that a lower element or component as mentioned below may also be an upper element or component within the technical spirit of the present disclosure.

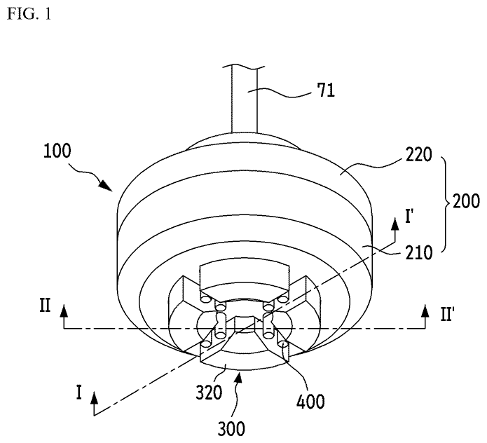

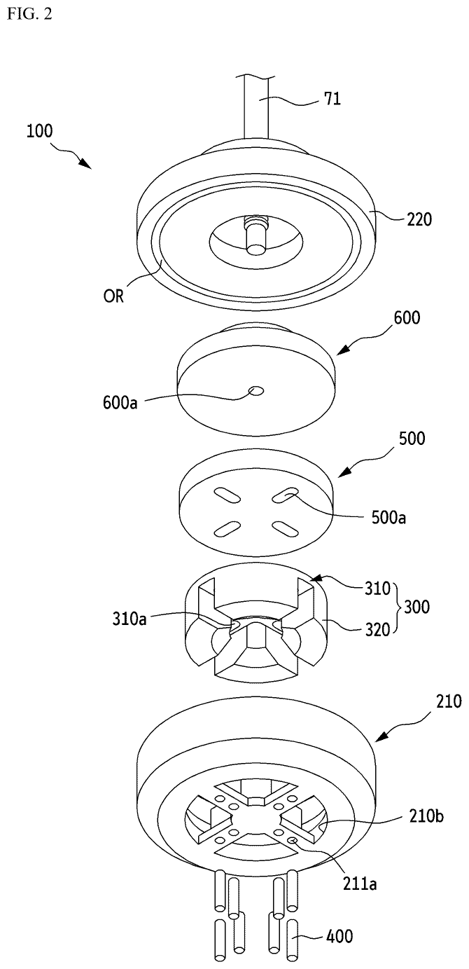

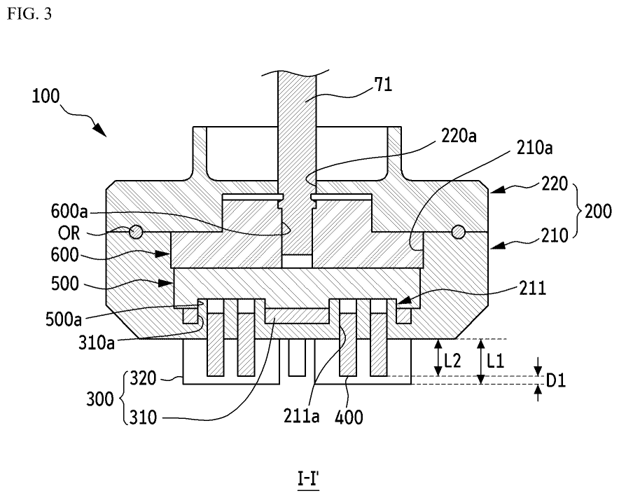

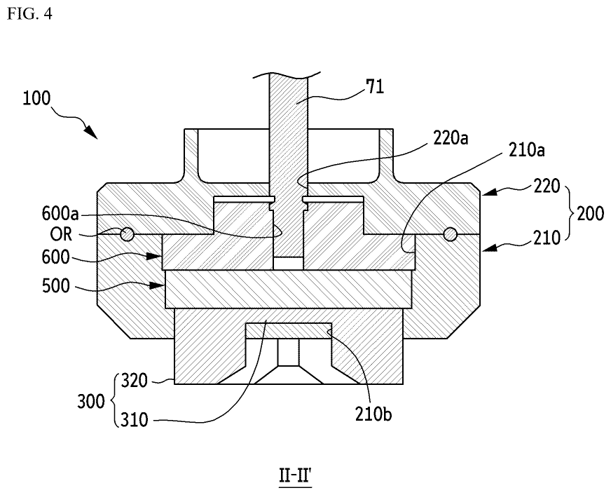

FIG. 1 is a view illustrating a substrate processing brush according to some embodiments of the present disclosure, FIG. 2 is an exploded view illustrating the substrate processing brush of FIG. 1, FIG. 3 is a cross-sectional view taken along line I-I′ of FIG. 1, and FIG. 4 is a cross-sectional view taken along line II-II′ of FIG. 1.

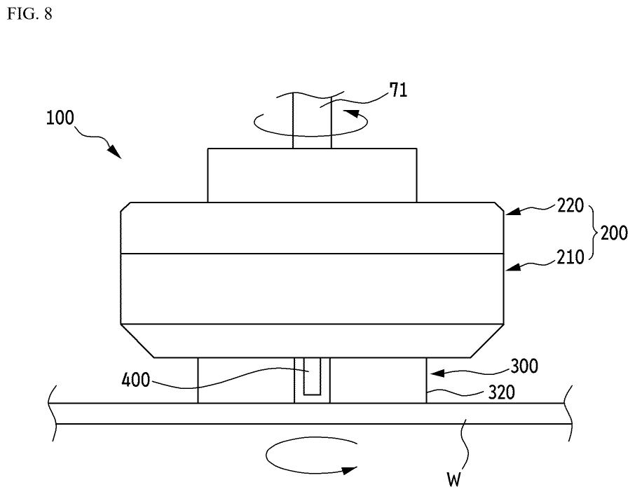

A substrate processing brush 100 may process the substrate W, such as a wafer or a glass substrate, as shown in FIG. 8. For example, the substrate processing brush 100 may clean one surface of the substrate W or may polish one surface of the substrate W.

Referring to FIGS. 1 to 4, the substrate processing brush 100 includes a holder 200, a substrate processing pad 300, a substrate processing sweeper 400, a pressing member 500, a shaft connection member 600, etc.

The holder 200 may support the substrate processing pad 300, the substrate processing sweeper 400, the pressing member 500, and the shaft connection member 600. A first portion of the substrate processing pad 300, the pressing member 500, and the shaft connection member 600 may be disposed inside the holder 200 so that the holder 200 may support the substrate processing pad 300, the substrate processing sweeper 400, the pressing member 500, and the shaft connection member 600. Also, the substrate processing sweeper 400 is connected to one surface of the holder 200 so that the holder 200 may support the substrate processing sweeper 400. For example, the holder 200 may have a cylindrical shape which is empty inside and has a height smaller than a width of a lower surface. The holder 200 includes a holder body 210, a holder cover 220, etc.

The holder body 210 may form the holder 200 together with the holder cover 220. An accommodation space 210a may be formed in the holder body 210. In the accommodation space 210a, a pad body portion 310 which are first portions of the substrate processing pad 300, the pressing member 500 and the shaft connection member 600, may be sequentially disposed in a vertical direction. An upper portion of the accommodation space 210a may be opened. The substrate processing pad 300, the pressing member 500 and the shaft connection member 600 may be sequentially inserted into and disposed in the accommodation space 210a through the open upper portion of the accommodation space 210a. Also, the shaft connection member 600, the pressing member 500, and the substrate processing pad 300 may be sequentially discharged from the accommodation space 210a through the open upper portion of the accommodation space 210a.

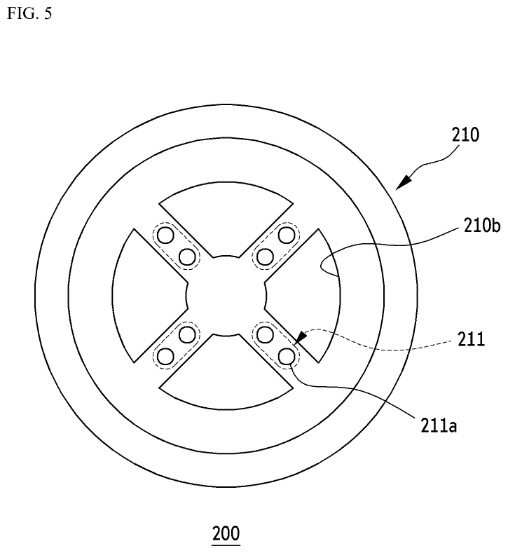

FIG. 5 is a bottom view illustrating the holder of the substrate processing brush of FIG. 1.

Referring to FIG. 5, a pad through hole 210b communicated with the accommodation space 210a may be formed on a lower surface of the holder body 210. A pad protrusion portion 320 to be described later, which is a second portion of the substrate processing pad 300, may pass through the pad through hole 210b. In a state that the pad body portion 310 of the substrate processing pad 300 is disposed in the accommodation space 210a, the pad protrusion portion 320 may be protruded to the outside of the holder 200 by passing through the pad through hole 210b.

There may be a plurality of pad through holes 210b. The plurality of pad through holes 210b may be formed on the lower surface of the holder body 210 so that they may be spaced apart from each other in a circumferential direction of the holder body 210. The number of pad through holes 210b may be the same as the number of pad protrusion portions 320. For example, the number of pad protrusion portions 320 may be four, as described below, and the number of pad through holes 210b may also be four. However, the number of pad through holes 210b is not limited to four, and may be changed depending on the number of pad through holes 320.

Referring back to FIGS. 2 to 4, the sweeper connection portion 211 to which the substrate processing sweeper 400 is connected may be formed in the holder body 210. The sweeper connection portion 211 may be formed to be extended to the accommodation space 210a on the lower surface of the holder body 210 between the pad through holes 210b in the circumferential direction of the holder body 210. The sweeper connection portion 211 may be formed to be extended upward from the lower surface of the holder body 210 between the pad through holes 210b in the circumferential direction of the holder body 210. The sweeper connection portion 211 may be formed on the lower surface of the holder body 210 between the pad through holes 210b in the circumferential direction of the holder body 210 so that it may be extended in a radial direction while being extended upward in the accommodation space 210a.

Referring back to FIG. 5, there may be a plurality of sweeper connection portions 211. The plurality of sweeper connection portions 211 may be formed on the lower surface of the holder body 210 so that they may be spaced apart from each other in the circumferential direction of the holder body 210. The number of sweeper connection portions 211 may be the same as the number of pad protrusion portions 320. For example, the number of pad protrusion portions 320 may be four, and the number of sweeper connection portions 211 may also be four. However, the number of sweeper connection portions 211 is not limited to four, and may be changed depending on the number of pad protrusion portions 320.

A sweeper connection hole 211a may be formed in the sweeper connection portion 211. One side of the substrate processing sweeper 400 may be inserted into and connected to the sweeper connection hole 211a. The sweeper connection hole 211a may be formed to be extended in the vertical direction in the sweeper connection portion 211, and an upper portion of the substrate processing sweeper 400 may be inserted into and connected to the sweeper connection hole 211a. There may be a plurality of sweeper connection holes 211a. The plurality of sweeper connection holes 211a may be formed in the sweeper connection portion 211 so that they may be spaced apart from each other on the lower surface of the holder body 210 in the radial direction. The plurality of sweeper connection holes 211a may be formed in the sweeper connection portion 211, and a plurality of substrate processing sweepers 400 may be connected to the plurality of sweeper connection holes 211a, respectively. For example, two sweeper connection holes 211a may be formed in the sweeper connection portion 211 so that they may be spaced apart from each other on the lower surface of the holder body 210 in the radial direction, and two substrate processing sweepers 400 may be connected to the two sweeper connection holes 211a, respectively. However, the number of sweeper connection holes 211a is not limited to two, and may be changed depending on processing conditions of the substrate W.

Referring back to FIGS. 2 to 4, the holder cover 220 may form the holder 200 together with the holder body 210. The holder cover 220 may be detachably connected to the holder body 210 so as to cover the open upper portion of the accommodation space 210a. As the holder cover 220 is separated from the holder body 210, the upper portion of the accommodation space 210a may be opened. Also, as the holder cover 220 is connected to the holder body 210, the upper portion of the accommodation space 210a may be covered by the holder cover 220. A shaft through hole 220a may be formed in the holder cover 220. A brush rotation shaft 71, which will be described later, may pass through the shaft through hole 220a. Although not shown as a separate reference numeral, a connection member insertion connection groove to which a portion of the shaft connection member 600 may be inserted and connected may be formed in the holder cover 220. The connection member insertion connection groove may be communicated with the shaft through hole 220a, and an upper portion of the shaft connection member 600 may be inserted and connected thereto.

A sealing member OR such as an O-ring may be disposed between the holder body 210 and the holder cover 220. Since the accommodation space 210a may be sealed by the sealing member OR, particles in the accommodation space 210a may be discharged to the outside of the holder 200 to prevent a defect of the substrate W, such as contamination of the substrate W or a scratch of the substrate W, from being caused.

The substrate processing pad 300 may process the substrate W. In a state that the substrate processing pad 300 is in contact with the one surface of the substrate W, one surface of the substrate W may be processed, for example, cleaned or polished. The substrate processing pad 300 may be detachably disposed in the holder 200. As the substrate processing pad 300 is detachably disposed in the holder 200, the substrate processing pad 300 may be separately replaced. Also, since the substrate processing pad 300 is not connected to the holder 200 by an adhesive or the like, contamination of the substrate W by the substrate processing brush 100 due to the adhesive may be avoided. The first portion of the substrate processing pad 300 may be disposed inside the holder 200 and supported by the holder 200. The second portion of the substrate processing pad 300 may be protruded to the outside by passing through one surface of the holder 200. The second portion of the substrate processing pad 300 protruded to the outside of the holder 200 may be in contact with one surface of the substrate W, and may process one surface of the substrate W.

A length at which the second portion of the substrate processing pad 300 is protruded from one surface of the holder 200 to the outside of the holder 200 may be referred to as a protruded length L1. Such a protruded length L1 may be greater than an extended length L2 to be described later, which is a length at which the substrate processing sweeper 400 is extended from one surface of the holder 200. Further, the substrate processing pad 300 may process one surface of the substrate W in a state that it is in contact with one surface of the substrate W, and the substrate processing sweeper 400 may remove particles or the like generated when the substrate processing pad 300 processes one surface of the substrate W in a state that it is not in contact with the substrate W.

When one surface of the substrate W is cleaned, a material forming the substrate processing pad 300 may be formed of a porous and elastic material. Also, the material forming the substrate processing pad 300 may be formed of a material having hardness smaller than that of a material forming the substrate processing sweeper 400. Since the substrate processing pad 300 comes into contact with one surface of the substrate W to clean one surface of the substrate W, the substrate processing pad 300 should prevent a scratch or the like from occurring on the substrate W when it comes into contact with one surface of the substrate W. For example, when one surface of the substrate W is cleaned, the substrate processing pad 300 may be formed of polyvinyl alcohol (PVA). Polyvinyl alcohol is porous and elastic. Also, since polyvinyl alcohol (PVA) is not easily crushed, when the substrate processing pad 300 is formed of polyvinyl alcohol, particles may be less generated during cleaning of the substrate W. The substrate processing pad 300 includes a pad body portion 310, a pad protrusion portion 320, etc.

The pad body portion 310 may support the pad protrusion portion 320. The pad protrusion portion 320 may be connected to the pad body portion 310, so that the pad body portion 310 may support the pad protrusion portion 320. The pad body portion 310 and the pad protrusion portion 320 may be integrally formed so that the pad protrusion portion 320 may be connected to the pad body portion 310. The pad body portion 310 may be disposed inside the holder 200. In other words, the pad body portion 310 may be the first portion of the substrate processing pad 300. The pad body portion 310 may be disposed in the accommodation space 210a of the holder 200. The substrate processing pad 300 may be disposed in the accommodation space 210a through the open upper portion of the accommodation space 210a of the holder body 210, and the pad body portion 310 may be disposed in the accommodation space 210a that is the inside of the holder 200. For example, the pad body portion 310 may have a disk shape.

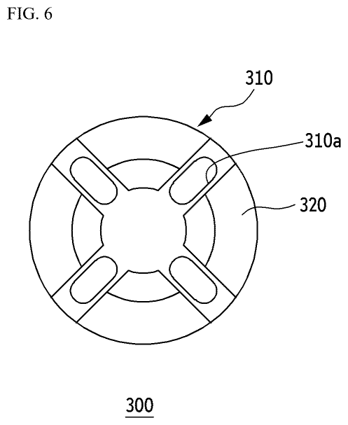

FIG. 6 is a bottom view illustrating a substrate processing pad of the substrate processing brush of FIG. 1.

Referring to FIG. 6, a connection portion insertion hole 310a may be formed in the pad body portion 310. The sweeper connection portion 211 of the holder 200 may be inserted into the connection portion insertion hole 310a. The connection portion insertion hole 310a may have a shape corresponding to that of the sweeper connection portion 211. For example, the connection portion insertion hole 310a may be extended in the radial direction while being extended in the vertical direction from the pad body portion 310. The connection portion insertion hole 310a may be formed in the pad body portion 310 between the pad protrusion portions 320 in the circumferential direction of the pad body portion 310. A plurality of connection portion insertion holes 310a may be provided. The plurality of connection portion insertion holes 310a may be disposed to be spaced apart from each other in the circumferential direction of the pad body portion 310. In addition, the plurality of connection portion insertion holes 310a may be disposed to be spaced apart from the center of the pad body portion 310. The number of connection portion insertion holes 310a may be the same as the number of sweeper connection portions 211. For example, the number of sweeper connection portions 211 may be four, and the number of connection portion insertion holes 310a may also be four. However, the number of connection portion insertion holes 310a is not limited to four, and may be changed depending on the number of sweeper connection portions 211.

Referring back to FIGS. 2 to 4, the pad protrusion portion 320 may be in contact with one surface of the substrate W to process one surface of the substrate W. The lower surface of the pad protrusion portion 320 may be in contact with the upper surface of the substrate W to process the upper surface of the substrate W. The pad protrusion portion 320 may be connected to the pad body portion 310. For example, the pad protrusion portion 320 and the pad body portion 310 may be integrally formed so that the pad protrusion portion 320 may be connected to the pad body portion 310. The pad protrusion portion 320 may have an upper portion connected to the pad body portion 310 and extended downward. The pad protrusion portion 320 having an upper portion connected to the pad body portion 310 and extended downward may be protruded downward from the lower surface of the holder 200 to the outside of the holder 200 as much as the protruded length L1 by passing through the lower surface of the holder 200. In other words, the pad protrusion portion 320 may be the second portion of the substrate processing pad 300.

The protruded length L1 at which the pad protrusion portion 320 is protruded downward from the lower surface of the holder 200 may be greater than the extended length L2 that is a length at which the substrate processing sweeper 400 is extended downward from the lower surface of the holder 200. Since the protruded length L1 is greater than the extended length L2, the pad protrusion portion 320 may be in contact with one surface of the substrate W to process one surface of the substrate W. In a state that the substrate processing sweeper 400 is not in contact with one surface of the substrate W, the substrate processing sweeper 400 may process the substrate W together with the pad protrusion portion 320. The substrate processing sweeper 400 may remove particles and the like generated when the substrate processing pad 300 processes one surface of the substrate W. Since the substrate processing sweeper 400 may process the substrate W in a state that it is not in contact with the substrate W, the substrate processing sweeper 400 may be prevented from causing a defect of the substrate W such as a scratch of the substrate W by being in contact with the substrate W.

A difference D1 between the protruded length L1 and the extended length L2 may be 0.2 mm to 0.8 mm. When the difference D1 between the protruded length L1 and the extended length L2 is less than 0.2 mm, the time for the substrate processing sweeper 400 to be in contact with the substrate W may be accelerated due to wear of the pad protrusion portion 320, which is caused by processing of one surface of the substrate W. Also, a replacement period of the substrate processing pad 300 may be shortened, and thus, it may not be economical. When the difference D1 between the protruded length L1 and the extended length L2 is greater than 0.8 mm, processing of the substrate W, such as removal of particles or the like by the substrate processing sweeper 400, may not be efficiently performed.

Referring back to FIG. 6, there may be a plurality of pad protrusion portions 320. The plurality of pad protrusion portions 320 may be connected to the pad body portion 310 so that they may be spaced apart from each other in the circumferential direction of the pad body portion 310. In addition, the plurality of pad protrusion portions 320 may be disposed to be spaced apart from the center of the pad body portion 310. For example, the pad protrusion portion 320 may have a shape of a portion of a fan shape as a whole when viewed from below. The pad protrusion portion 320 may have a fan shape in which a pointed portion is removed in a smaller fan shape when viewed from below. For example, the number of pad protrusion portions 320 may be four, but is not limited thereto. The number of pad protrusion portions 320 may be changed depending on the processing conditions of the substrate W.

Referring back to FIGS. 2 to 4, the substrate processing sweeper 400 may process the substrate W together with the substrate processing pad 300. The substrate processing sweeper 400 may remove particles and the like generated when the substrate processing pad 300 processes one surface of the substrate W. The substrate processing sweeper 400 may be connected to the holder 200. The substrate processing sweeper 400 is connected to one surface of the holder 200 so that it may be adjacent to the second portion of the substrate processing pad 300, which is protruded to the outside of the holder 200, and may be extended from one surface of the holder 200. The substrate processing sweeper 400 may have an upper portion connected to the lower surface of the holder 200 and may be extended downward from the lower surface of the holder 200 as much as the extended length L2 smaller than the protruded length L1 so that it may be adjacent to the pad protrusion portion 320 which is the second portion of the substrate processing pad 300. For example, the substrate processing sweeper 400 may have a cylindrical shape as a whole, and may include a plurality of brushes.

The substrate processing sweeper 400 may be disposed to be spaced apart from the pad protrusion portion 320 between the pad protrusion portions 320 in the circumferential direction of the pad body portion 310. The substrate processing sweeper 400 may have an upper portion connected to the lower surface of the holder body 210 between the pad through holes 210b in the circumferential direction of the holder body 210. The upper portion of the substrate processing sweeper 400 may be inserted into the sweeper connection hole 211a of the holder body 210 and thus connected to the lower surface of the holder body 210. For example, the upper portion of the substrate processing sweeper 400 may be connected to the sweeper connection portion 211 by a sweeper connection member such as a connection string which is not shown in a state that it is inserted into the sweeper connection hole 211a. Since the substrate processing sweeper 400 is not connected to the holder 200 by an adhesive or the like, contamination of the substrate W by the substrate processing brush 100 due to the adhesive may be avoided.

When there are a plurality of pad protrusion portions 320 and the pad protrusion portions 320 are connected to the pad body portion 310 by being spaced apart from each other in the circumferential direction of the pad body portion 310, each substrate processing sweeper 400 may be disposed to be spaced apart from the pad protrusion portion 320 between the pad protrusion portions 320 in the circumferential direction of the pad body portion 310.

The plurality of substrate processing sweepers 400 may be disposed to be spaced apart from the pad protrusion portions 320 between the pad protrusion portions 320 in the circumferential direction of the pad body portion 310. The plurality of substrate processing sweepers 400 may be disposed to be spaced apart from the substrate processing pad 300 in the radial direction. For example, two substrate processing sweepers 400 may be disposed to be spaced apart from the pad protrusion portions 320 between the pad protrusion portions 320 in the circumferential direction of the pad body portion 310 and disposed to be spaced apart from each other in the substrate processing pad 300 in the radial direction. When there are a plurality of pad protrusion portions 320 and the pad protrusion portions 320 are connected to the pad body portion 310 by being spaced apart from each other in the circumferential direction of the pad body portion 310, the plurality of substrate processing sweepers 400 may be disposed to be spaced apart from the pad protrusion portion 320 between the pad protrusion portions 320 in the circumferential direction of the pad body portion 310. For example, two substrate processing sweepers 400 may be disposed to be spaced apart from the pad protrusion portions 320 between the pad protrusion portions 320 in the circumferential direction of the pad body portion 310.

When one surface of the substrate W is cleaned, a material forming the substrate processing sweeper 400 may have hardness greater than that of a material forming the substrate processing pad 300. Since the extended length L2 is less than the protruded length L1, the substrate processing sweeper 400 processes the substrate W by removing particles, etc. in a state that it is not in contact with one surface of the substrate W. Therefore, even though the material for forming the substrate processing sweeper 400 has hardness greater than that of the material for forming the substrate processing pad 300, there may be no concern that the substrate processing sweeper 400 may come into contact with the substrate W unless the protruded length L1 is the same as or less than the extended length L2 due to wear of the substrate processing pad 300. Also, unless the protruded length L1 is the same as or less than the extended length L2, it may be difficult for the substrate processing sweeper 400 to come into contact with the substrate W and cause a defect in the substrate W by causing a scratch or the like. For example, when one surface of the substrate W is cleaned, the substrate processing sweeper 400 may be formed of polypropylene (PP) or nylon.

The pressing member 500 may prevent the substrate processing pad 300 from moving inside the holder 200 when the substrate processing brush 100 rotates. In other words, the pressing member 500 may fix the substrate processing pad 300 inside the holder 200 when the substrate processing brush 100 rotates. The pressing member 500 may be disposed inside the holder 200 to bring the substrate processing pad 300 into close contact with the holder 200. The pressing member 500 may be disposed in the accommodation space 210a of the holder 200 to bring the pad body portion 310 of the substrate processing pad 300 into close contact with the holder body 210 of the holder 200. For example, the pressing member 500 may have a disk shape.

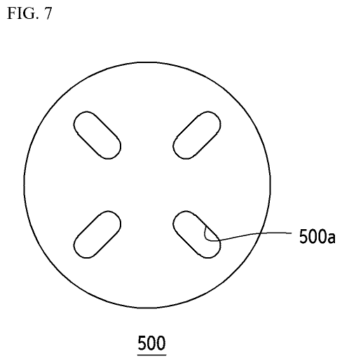

FIG. 7 is a bottom view illustrating a pressing member of the substrate processing brush of FIG. 1.

Referring to FIG. 7, a connection portion insertion groove 500a may be formed in the pressing member 500. The sweeper connection portion 211 of the holder 200, which has passed through a connection portion insertion hole 310a of the substrate processing pad 300, may be inserted into the connection portion insertion groove 500a.

The connection portion insertion groove 500a may have a shape corresponding to that of the sweeper connection portion 211. For example, the connection portion insertion groove 500a may be extended in the radial direction from the pressing member 500. There may be a plurality of connection portion insertion grooves 500a. The plurality of connection portion insertion grooves 500a may be disposed to be spaced apart from each other in the circumferential direction of the pressing member 500. Furthermore, the plurality of connection portion insertion grooves 500a may be disposed to be spaced apart from the center of the pressing member 500. The number of connection portion insertion grooves 500a may be the same as the number of sweeper connection portions 211. For example, the number of sweeper connection portions 211 may be four, and the number of connection portion insertion grooves 500a may also be four. However, the number of connection portion insertion grooves 500a is not limited to four, and may be changed depending on the number of sweeper connection portions 211.

Referring back to FIGS. 2 to 4, the shaft connection member 600 may transfer a rotational force of the brush rotation shaft 71 to the substrate processing brush 100. The rotational force of the brush rotation shaft 71 may be transferred to the substrate processing brush 100 by the shaft connection member 600, and thus the substrate processing brush 100 may be rotated around the brush rotation shaft 71. The shaft connection member 600 may be disposed inside the holder 200 between the upper surface of the holder 200 and the pressing member 500. The shaft connection member 600 may be disposed in the accommodation space 210a between the holder cover 220 of the holder 200 and the pressing member 500. The shaft connection member 600 may be connected to the brush rotation shaft 71 passing through the upper surface of the holder 200. The shaft connection member 600 may be connected to the brush rotation shaft 71 passing through the upper surface of the holder cover 220. A portion of the shaft connection member 600 may be inserted into and connected to the holder cover 220 of the holder 200. The upper portion of the shaft connection member 600 may be inserted into and connected to the connection member insertion connection groove of the holder cover 220.

The shaft connection member 600 may be formed of metal. Since the brush rotation shaft 71 is formed of metal, when the shaft connection member 600 is formed of metal, the brush rotation shaft 71 may be firmly connected to the shaft connection member 600. Also, the transfer of the rotational force of the brush rotation shaft 71 to the substrate processing brush 100 through the shaft connection member 600 may be reliably performed for a long time. For example, the shaft connection member 600 may be formed of aluminum, but the metal forming the shaft connection member 600 is not limited thereto. Any metal may be used as far as the brush rotation shaft 71 may be connected and the rotational force of the brush rotation shaft 71 may be transferred to the substrate processing brush 100.

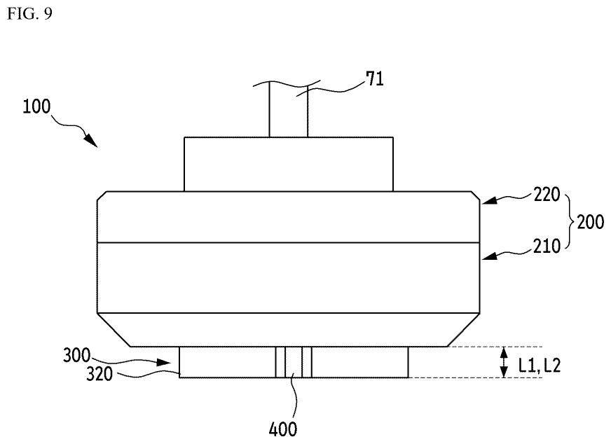

FIG. 8 is a view illustrating that one surface of the substrate is processed by the substrate processing brush of FIG. 1, and FIG. 9 is a view illustrating that the substrate processing pad of the substrate processing brush FIG. 1 is worn away, so that the protruded length of the substrate processing pad is the same as or smaller than the extended length of the substrate processing sweeper.

Referring to FIG. 8, in a state that the substrate processing pad 300 of the substrate processing brush 100 is in contact with one surface of the substrate W, the substrate processing brush 100 may be rotated so that one surface of the substrate W may be processed, for example, cleaned or polished by the substrate processing pad 300 and the substrate processing sweeper 400 of the substrate processing brush 100. For example, in a state that the lower surface of the substrate processing pad 300 is in contact with the upper surface of the substrate W, the substrate processing brush 100 may be rotated so that the upper surface of the substrate W may be processed, for example, cleaned or polished by the substrate processing pad 300 and the substrate processing sweeper 400. While the substrate processing brush 100 rotates to process one surface of the substrate W through the substrate processing pad 300 and the substrate processing sweeper 400, the substrate W may also rotate.

Referring to FIG. 9, when the processing of the substrate W by the substrate processing brush 100 continues, one surface of the substrate processing pad 300 that is in contact with one surface of the substrate W may be worn away. Also, the protruded length L1 of the substrate processing pad 300 may be the same as or smaller than the extended length L2 of the substrate processing sweeper 400. When the protruded length L1 becomes the same as or smaller than the extended length L2, the substrate processing sweeper 400 may be in contact with one surface of the substrate W. When the substrate processing sweeper 400 is in contact with one surface of the substrate W, a defect in the substrate W such as a scratch on one surface of the substrate W may be caused. In this case, the substrate processing pad 300 has to be replaced.

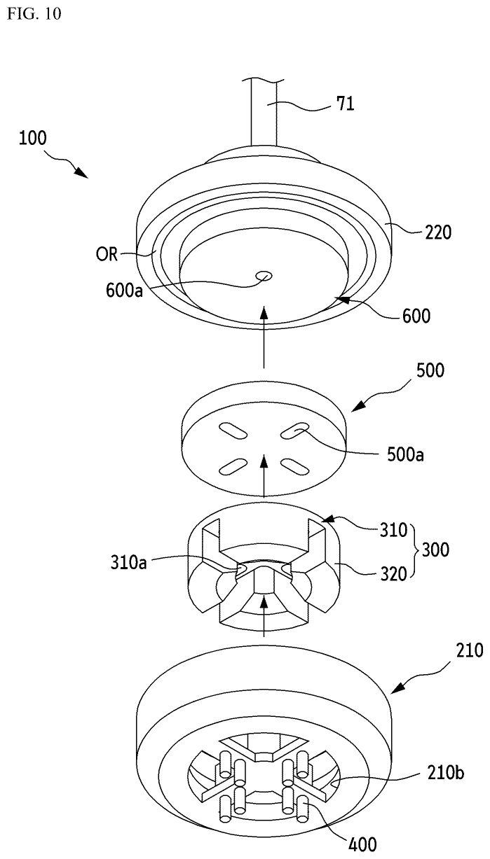

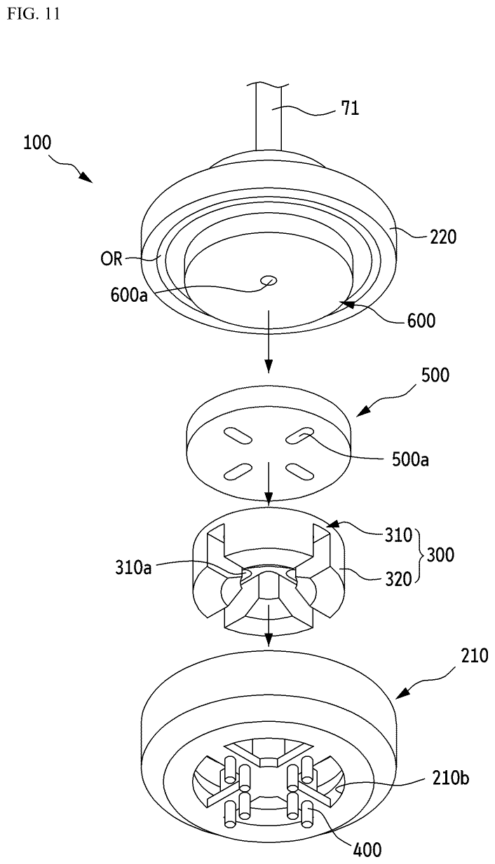

FIGS. 10 and 11 are views illustrating replacement of a substrate processing pad of the substrate processing brush of FIG. 1.

Referring to FIG. 10, in order to replace the substrate processing pad 300, the holder cover 220 may be separated from the holder body 210 so that the upper portion of the accommodation space 210a of the holder body 210 may be opened.

As the holder cover 220 is separated from the holder body 210, the shaft connection member 600 connected to the brush rotation shaft 71 may be taken out from the accommodation space 210a of the holder body 210 toward the outside. In addition, the pressing member 500 and the substrate processing pad 300 remain in the accommodation space 210a of the holder body 210. The pressing member 500 and the substrate processing pad 300, which remain in the accommodation space 210a, may be sequentially or together taken out from the accommodation space 210a through the open upper portion of the accommodation space 210a of the holder body 210.

Referring to FIG. 11, after the pressing member 500 and the substrate processing pad 300 are taken out from the accommodation space 210a of the holder body 210, a new substrate processing pad 300 may be disposed in the accommodation space 210a through the open upper portion of the accommodation space 210a. While the new substrate processing pad 300 is disposed in the accommodation space 210a, the pad protrusion portion 320 of the substrate processing pad 300 may be protruded outward by passing through the pad through hole 210b of the holder body 210. In addition, the sweeper connection portion 211 of the holder 200 may be inserted into the connection portion insertion hole 310a of the substrate processing pad 300.

When the substrate processing pad 300 is disposed in the accommodation space 210a of the holder body 210 so that the pad protrusion portion 320 is protruded outward, the pressing member 500 may be disposed in the accommodation space 210a so that the pad body portion 310 of the substrate processing pad 300 is in close contact with the holder body 210. As the pressing member 500 is disposed in the accommodation space 210a, the sweeper connection portion 211, which is inserted into the connection portion insertion hole 310a of the substrate processing pad 300 and passes through the connection portion insertion hole 310a, may be inserted into the connection portion insertion groove 500a of the pressing member 500.

After the pressing member 500 is disposed in the accommodation space 210a of the holder body 210, the shaft connection member 600 connected to the brush rotation shaft 71 may be disposed in the accommodation space 210a while the holder cover 220 is connected to the holder body 210.

As described above, when the substrate processing pad 300 is worn away so that the protruded length L1 of the substrate processing pad 300 becomes the same as or smaller than the extended length L2 of the substrate processing sweeper 400, the substrate processing pad 300 may be separately replaced. Since the substrate processing pad 300 may be separately replaced, the maintenance cost of the substrate processing brush 100 may be reduced. Also, since the substrate processing pad 300 and the substrate processing sweeper 400 are not connected to the holder 200 by an adhesive or the like, contamination of the substrate W by the substrate processing brush 100 due to the adhesive or the like may be avoided.

Hereinafter, a substrate processing apparatus according to some embodiments of the present disclosure will be described.

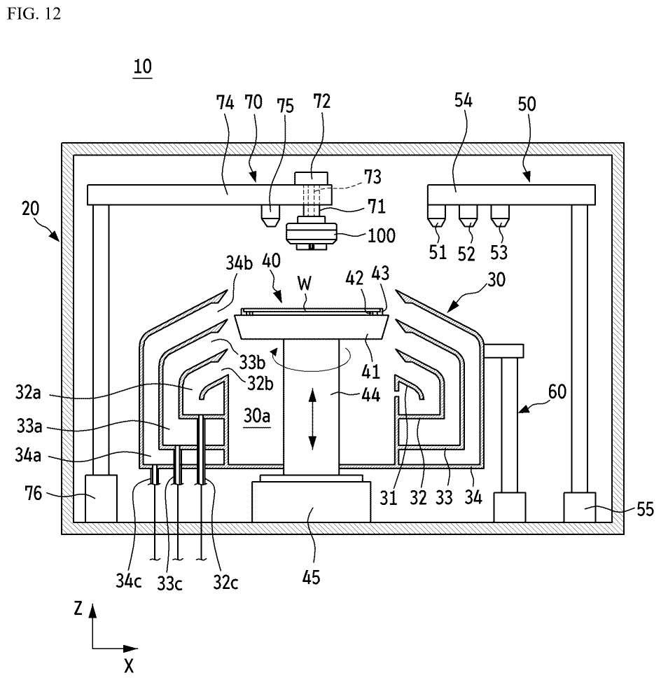

FIG. 12 is a view illustrating a substrate processing apparatus according to some embodiments of the present disclosure.

Referring to FIG. 12, the substrate processing apparatus 10 may process the substrate W. For example, the substrate processing apparatus 10 may process, for example, clean or polish one surface of the substrate W. The substrate processing apparatus 10 includes a housing 20, a processing container 30, a support unit 40, a processing liquid supply unit 50, an elevation unit 60, and a brush unit 70.

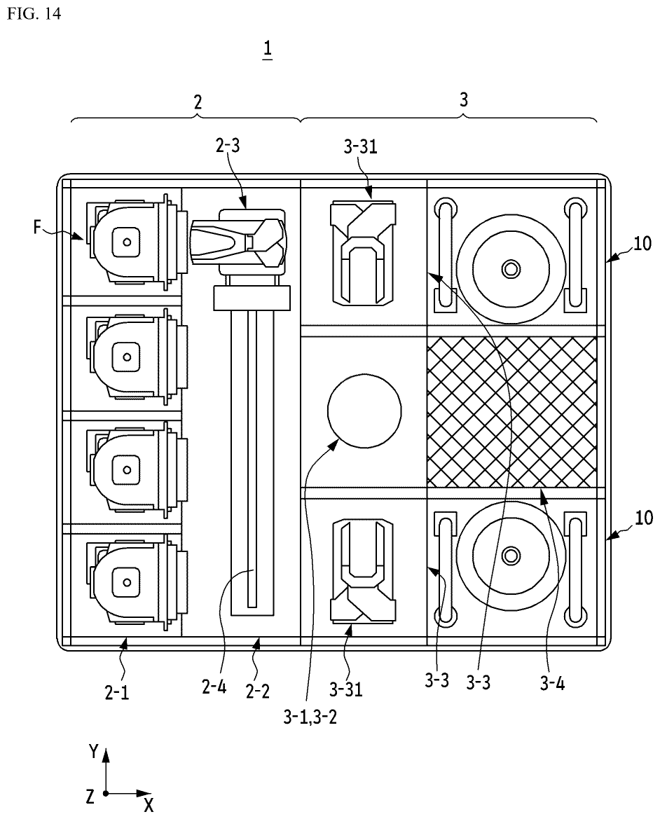

The housing 20 may have a generally rectangular parallelepiped shape. Although not shown, a carry-in port may be formed in a sidewall of the housing 20. The substrate W may be carried in or out of the housing 20 through the carry-in port. The carry-in port may be formed on a sidewall, which is opposite to a transfer chamber 3-3 (see FIG. 14), among sidewalls of the housing 20. The substrate W may be carried in or out of the housing 20 by a transfer robot 3-31 (see FIG. 14). The processing container 30, the support unit 40, the processing liquid supply unit 50, the elevation unit 60 and the brush unit 70 may be disposed inside the housing 20.

The processing container 30 may be a bowl of which upper portion is open. A processing space 30a with an open upper portion may be formed in the processing container 30. The substrate W may be processed in the processing space 30a. For example, one surface of the substrate W may be processed, for example, cleaned or polished, in the processing space 30a. The processing container 30 includes a guide wall 31, a plurality of recovery containers 32, 33 and 34, etc.

The guide wall 31 may have a ring shape surrounding the support unit 40.

The plurality of recovery containers 32, 33 and 34 may have a ring shape surrounding the support unit 40. Recovery spaces 32a, 33a and 34a for separating and recovering different processing liquids among those used for processing the substrate W may be formed in the recovery containers 32, 33 and 34, respectively. When the processing liquid is supplied while the substrate W is processed, the processing liquid scattered by rotation of the substrate W may flow into the recovery spaces 32a, 33a and 34a through inlets 32b, 33b and 34b of the recovery containers 32, 33 and 34. Processing liquid discharge pipes 32c, 33c and 34c for discharging the processing liquid may be connected to the recovery containers 32, 33 and 34, respectively. The processing liquid discharged through the processing liquid discharge pipes 32c, 33c and 34c may be reused using an external regeneration system. The number of recovery containers may be variously changed depending on the number of processing liquids to be used or the number of processing liquids to be recovered or discarded. Although not shown, an exhaust line for exhausting a fume and gas may be connected to a bottom surface of the processing container 30.

For example, the processing container 30 may include a first recovery container 32, a second recovery container 33, and a third recovery container 34. The first recovery container 32 may be disposed to surround the support unit 40, the second recovery container 33 may be disposed to surround the first recovery container 32, and the third recovery container 34 may be disposed to surround the second recovery container 33. The first inlet 32b through which the processing liquid flows into the first recovery space 32a of the first recovery container 32 may be positioned below the second inlet 33b through which the processing liquid flows into the recovery space 33a of the second recovery container 33. Furthermore, the second inlet 33b may be positioned below the third inlet 34b through which the processing liquid flows into the third recovery space 34a of the third recovery container 34. The first processing liquid discharge pipe 32c may be connected to the first recovery container 32, the second processing liquid discharge pipe 33c may be connected to the second processing liquid recovery container 33, and the third processing liquid discharge pipe 34c may be connected to the third processing liquid recovery container 34.

The support unit 40 may support the substrate W in the processing space 30a. Also, the support unit 40 may rotate the substrate W in the processing space 30a. The support unit 40 includes a spin chuck 41, a support pin 42, a chuck pin 43, a driving shaft 44, a chuck driver 45, etc.

An upper surface of the spin chuck 41 may be formed in a substantially circular shape. Also, the upper surface of the spin chuck 41 may have a diameter larger than that of the substrate W.

The support pin 42 may support the substrate W. The support pin 42 may be disposed at an upper portion of the spin chuck 41. The support pin 42 may be disposed such that its upper end is protruded upward from the upper surface of the spin chuck 41. The substrate W may be supported by being spaced apart from the upper surface of the spin chuck 41 as much as a predetermined distance by the support pin 42. There may be a plurality of support pins 42.

The chuck pin 43 may support a side portion of the substrate W so that the substrate W does not deviate laterally from a regular position on the support unit 40 when the substrate W rotates. The chuck pin 43 may be disposed such that its upper end is protruded from the upper surface of the spin chuck 41.

The driving shaft 44 is driven by the chuck driver 45, and may be connected to the spin chuck 41. The driving shaft 44 may be rotated by receiving a rotational force from the chuck driver 45. The spin chuck 41 connected to the driving shaft 44 and the substrate W supported by the spin chuck 41 may be also rotated around the driving shaft 44 by the rotation of the driving shaft 44.

The chuck driver 45 may move the spin chuck 41 in the vertical direction while rotating the spin chuck 41.

The processing liquid supply unit 50 may supply the processing liquid to the substrate W supported by the support unit 40. The processing liquid supply unit 50 includes nozzles 51, 52 and 53, a nozzle arm 54, a nozzle arm driver 55, etc.

The nozzles 51, 52 and 53 may supply the processing liquid to the substrate W when the substrate W is processed. The nozzles 51, 52 and 53 may supply different processing liquids to the substrate W when the substrate W is processed.

For example, the processing liquid supply unit 50 may include a first nozzle 51, a second nozzle 52, and a third nozzle 53. When one surface of the substrate W is cleaned, the first nozzle 51 may supply chemicals to the substrate W supported by the support unit 40. Also, the second nozzle 52 may supply water onto the substrate W supported by the support unit 40. For example, water may be pure water or deionized water. Also, the third nozzle 53 may supply an organic solvent onto the substrate W supported by the support unit 40. For example, the organic solvent may be isopropyl alcohol.

The nozzle arm 54 may support the nozzles 51, 52 and 53. The nozzle arm 54 may be connected to the nozzle arm driver 55.

The nozzle arm driver 55 may swing or linearly move the nozzle arm 54. The nozzles 51, 52 and 53 may be moved between a standby position and a processing liquid supply position by the nozzle arm driver 55. The standby position may be a position where the nozzles 51, 52 and 53 are on standby when the processing liquid is not supplied to the substrate W. For example, in the standby position, the nozzles 51, 52 and 53 may be positioned in an outer region of the processing container 30 when viewed from above. The processing liquid supply position may be a position where the nozzles 51, 52 and 53 supply the processing liquid to the substrate W. For example, in the processing liquid supply position, the nozzles 51, 52 and 53 may be positioned in an inner region of the processing container 30 when viewed from above.

The elevation unit 60 may adjust a relative height between the processing container 30 and the support unit 40. The elevation unit 60 may change the position of the processing container 30. For example, the elevation unit 60 may move the processing container 30 in the vertical direction. The relative height between the processing container 30 and the substrate W supported by the support unit 40 may be changed by the vertical movement of the processing container 30. Furthermore, the recovery containers 32, 33 and 34 may recover the processing liquid by separating the processing liquid in accordance with a type of the processing liquid supplied to the substrate W.

The brush unit 70 may process the substrate W supported by the support unit 40. For example, the brush unit 70 may process, for example, clean or polish one surface of the substrate W.

The brush unit 70 includes a substrate processing brush 100, a brush rotation shaft 71, a brush rotation shaft driver 72, an elastic member 73, a brush arm 74, a cleaning nozzle 75, a brush arm driver 76, etc.

Since the substrate processing brush 100 has been described above, its description will be omitted below. The position of the substrate processing brush 100 may be changed by the brush rotation shaft driver 72 and/or the brush arm driver 76. The substrate processing brush 100 may be moved between a standby position and a process position by the brush rotation shaft driver 72 and/or the brush arm driver 76. The standby position may be a position at which the substrate processing brush 100 is on standby when the brush unit 70 does not process the substrate W. For example, in the standby position, the substrate processing brush 100 may be positioned in the outer region of the processing container 30 when viewed from above. The process position may be a position at which the substrate processing pad 300 of the substrate processing brush 100 may be in contact with the substrate W. For example, in the process position, the substrate processing brush 100 may be positioned in the inner region of the processing container 30 when viewed from above.

The brush rotation shaft 71 may transfer a rotational force of the brush rotation shaft driver 72 to the substrate processing brush 100. The brush rotation shaft 71 may be connected to the brush rotation shaft driver 72 and the substrate processing brush 100. The brush rotation shaft 71 may generally have a rod shape. The brush rotation shaft 71 may pass through the brush arm 74. The brush rotation shaft 71 may be connected to the brush rotation shaft driver 72 disposed on the upper end of the brush arm 74 by passing through the brush arm 74. One end of the brush rotation shaft 71 may be connected to the brush rotation shaft driver 72, and the other end thereof may be connected to the shaft connection member 600 of the substrate processing brush 100. An upper end of the brush rotation shaft 71 may be connected to the brush rotation shaft driver 72, and a lower end thereof may be connected to the shaft connection member 600.

The brush rotation shaft driver 72 may rotate the substrate processing brush 100 with the brush rotation shaft 71 as a central shaft. Also, the brush rotation shaft driver 72 may move the substrate processing brush 100 in the vertical direction via the brush rotation shaft 71. For example, the brush rotation shaft driver 72 may be a motor.

The elastic member 73 may mitigate a pressure applied to one surface of the substrate W when the substrate processing pad 300 of the substrate processing brush 100 processes one surface of the substrate W in contact with one surface of the substrate W. The substrate W may be prevented from being damaged by the pressure mitigation by the elastic member 73. The elastic member 73 may be disposed inside the brush rotation shaft 71. The elastic member 73 may be disposed from the upper end of the brush rotation shaft 71 to the lower end of the brush rotation shaft 71. For example, the elastic member 73 may be a spring.

The brush arm 74 may support the substrate processing brush 100 and the cleaning nozzle 75. The brush arm 74 may be connected to the brush arm driver 76. The brush arm 74 may be moved in the vertical direction by the brush arm driver 76 such that the substrate processing brush 100 may be moved in the vertical direction. Also, the brush arm 74 may be swing-moved by the brush arm driver 76.

The processing liquid nozzle 75 may discharge the processing liquid to the substrate W. The processing liquid nozzle 75 may discharge the processing liquid to one surface of the substrate W supported by the support unit 40. When one surface of the substrate W is cleaned, the processing liquid nozzle 75 may discharge a cleaning liquid to one surface of the substrate W. For example, the cleaning liquid may be pure water or deionized water. The processing liquid nozzle 75 may be disposed on the brush arm 74. A lower end of the processing liquid nozzle 75 may be positioned above the lower end of the substrate processing pad 300 of the substrate processing brush 100.

The brush arm driver 76 may move the brush arm 74 in the vertical direction. Also, the brush arm driver 76 may swing the brush arm 74. The brush arm driver 76 may include a plurality of motors. Any one of a plurality of motors may be a linear motor, and the other one may be a rotation motor.

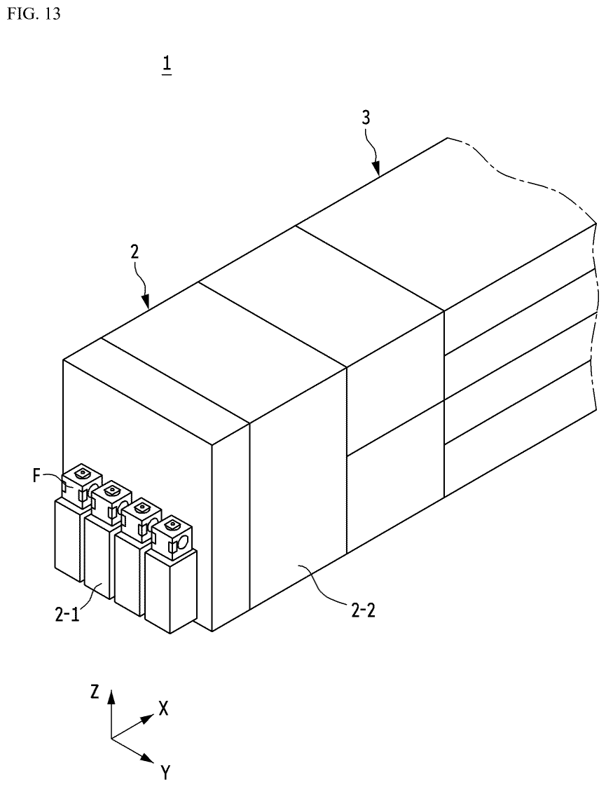

FIG. 13 is a view illustrating a substrate processing facility to which a substrate processing apparatus according to some embodiments of the present disclosure may be applied, and FIG. 14 is a cross-sectional view illustrating the substrate processing facility of FIG. 13.

Referring to FIGS. 13 and 14, in the substrate processing facility 1, the substrate W to be processed is transferred and processed, and the processed substrate W may be transferred to another facility. The substrate processing facility 1 includes an index block 2, a processing block 3, etc. The index block 2 and the processing block 3 may be disposed in one direction. Hereinafter, a direction in which the index block 2 and the processing block 3 are disposed is defined as a first direction X, a direction perpendicular to the first direction X when viewed from above is defined as a second direction Y, and a direction perpendicular to a plane including both the first direction X and the second direction Y is defined as a third direction Z.

The index block 2 may transfer the substrate W between a substrate storage container F in which the substrate W is accommodated and the processing block 3. The index block 2 may transfer the substrate W to be processed in the processing block 3 from the substrate storage container F to the processing block 3. Also, the index block 2 may transfer the substrate W processed in the processing block 3 to the substrate storage container F. For example, the index block 2 may have a longitudinal direction parallel with the first direction X. The index block 2 includes a load port 2-1, an index frame 2-2, a transfer robot 2-3, a transfer rail 2-4, etc.

The substrate storage container F in which the substrate W is accommodated may be seated on the load port 2-1. The load port 2-1 may be disposed on an opposite side of the processing block 3 based on the index frame 2-2. There may be a plurality of load ports 2-1. For example, the plurality of load ports 2-1 may be disposed along the second direction Y. The number of load ports 2-1 may be increased or reduced depending on process efficiency of the processing block 3, foot print conditions, and the like.

Meanwhile, a sealing container such as a front opening unified pod (FOUP) may be used as the substrate storage container F. The substrate storage container F may be placed in the load port 12 by a transfer means, such as an overhead transfer, an overhead conveyor or an automatic guided vehicle, or a worker.

A transfer space for transferring the substrate W may be formed in the index frame 2-2. The index robot 2-3 and the index rail 2-4 may be disposed in the transfer space of the index frame 2-2. For example, the index frame 2-2 may have a longitudinal direction parallel with the first direction X.

The index robot 2-3 may transfer the substrate W inside the transfer space. The index robot 2-3 may transfer the substrate W between the index block 2 and the processing block 3. The index robot 2-3 may transfer the substrate W to be processed, which is accommodated in the substrate storage container F, to a buffer unit 3-1 or an inverting unit 3-2 of the processing block 3, which will be described later. Also, the index robot 2-3 may transfer the substrate W processed in the substrate processing apparatus 10 to the substrate storage container F, which remains in the buffer unit 3-1 or the inverting unit 3-2.

The index robot 2-3 may be placed on the index rail 2-4, and the index robot 2-3 may linearly move along the index rail 2-4. In other words, the index robot 2-3 may move forward and backward along the index rail 2-4. For example, the index rail 2-4 may be extended in the second direction Y.

The processing block 3 may process the substrate W transferred from the index block 2. The processing block 3 includes a buffer unit 3-1, an inverting unit 3-2, a transfer chamber 3-3, a component storage space 3-4, a substrate processing apparatus 10, etc.

A buffer space may be formed in the buffer unit 3-1. The substrate W which is being transferred between the substrate storage container F and the substrate processing apparatus 10 may temporarily remain in the buffer space. A substrate to be processed in the substrate processing apparatus 10 or the substrate W processed in the substrate processing apparatus 10 may remain in the buffer space. The buffer unit 3-1 may be disposed to be adjacent to the index frame 2-2. For example, the buffer unit 3-1 and the index frame 2-2 may be arranged in the first direction X.

The inverting unit 3-2 may invert a position of the substrate W. There may be a plurality of inverting units 3-2. For example, the plurality of inverting units 3-2 may be disposed to be stacked in the vertical direction. The inverting unit 3-2 may be disposed to be stacked with the buffer unit 3-1 in the vertical direction. For example, the inverting unit 3-2 may be disposed above the buffer unit 3-1.

The transfer robot 3-31 and a guide rail (not shown) may be disposed in the transfer chamber 3-3. The guide rail may have a longitudinal direction parallel with the vertical direction. The transfer robot 3-31 may move along the guide rail. In other words, the guide rail may guide the vertical movement of the transfer robot 3-31. The substrate W to be processed, which remains in the buffer unit 3-1 or is inverted in the position in the inverting unit 3-2, may be transferred to the substrate processing apparatus 10 by the transfer robot 3-31. Furthermore, the substrate W processed in the substrate processing apparatus 10 may be transferred to the buffer unit 3-1 or the inverting unit 3-2 by the transfer robot 3-3. The transfer chamber 3-3 may be disposed to be adjacent to the buffer unit 3-1 or the inverting unit 3-2. There may be a plurality of transfer chambers 3-3.

A component may be accommodated in the component storage space 3-4. The component accommodated in the component storage space 3-4 may include electrical components, valve units, etc. Optionally, the components accommodated in the component storage space 3-4 may include various types of components used in a liquid supply system in addition to the electrical components or the valve units.

The substrate processing apparatus 10 may process the substrate W transferred by the transfer robot 3-31. For example, the substrate processing apparatus 10 may process, for example, clean or polish one surface of the substrate W. The substrate W processed in the substrate processing apparatus 10 may be transferred to the buffer unit 3-1 or the inverting unit 3-2 by the transfer robot 3-31. The substrate processing apparatus 10 may be disposed to be adjacent to the transfer chamber 3-3. There may be a plurality of substrate processing apparatuses 10. Since the substrate processing apparatus 10 has been described above, its description will be omitted below.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A substrate processing brush comprising:
a holder;
a substrate processing pad detachably disposed in the holder, processing the substrate; and
a substrate processing sweeper connected to the holder, processing the substrate together with the substrate processing pad,
wherein a first portion of the substrate processing pad is disposed inside the holder, and a second portion of the substrate processing pad is protruded to the outside of the holder by passing through one surface of the holder, and
the substrate processing sweeper is connected to one surface of the holder so that it is to be adjacent to the second portion of the substrate processing pad protruded to the outside of the holder, and is extended from one surface of the holder.

2. The substrate processing brush of claim 1, wherein a protruded length, which is a length at which the second portion of the substrate processing pad is protruded from one surface of the holder to the outside of the holder, is greater than an extended length, which is a length at which the substrate processing sweeper is extended from one surface of the holder.

3. The substrate processing brush of claim 2, wherein a difference between the protruded length and the extended length is 0.2 mm to 0.8 mm.

4. The substrate processing brush of claim 1, wherein the substrate processing pad includes
a pad body portion disposed inside the holder, and
a pad protrusion portion having an upper portion connected to the pad body portion, protruded downward as much as a protruded length from a lower surface of the holder to the outside of the holder by passing through a lower surface of the holder, and
the substrate processing sweeper has an upper portion connected to the lower surface of the holder so that it is to be adjacent to the pad protrusion portion, and is extended downward as much as an extended length smaller than the protruded length from the lower surface of the holder.

5. The substrate processing brush of claim 4, wherein the holder includes
a holder body in which the pad body portion is disposed and an accommodation space with an open upper portion is formed, and
a holder cover detachably connected to the holder body to cover the open upper portion of the accommodation space.

6. The substrate processing brush of claim 5, wherein a pad through hole, which is communicated with the accommodation space and through which the pad protrusion portion passes, is formed on a lower surface of the holder body.

7. The substrate processing brush of claim 6, wherein the pad protrusion portion is provided as a plurality of pad protrusion portions,
the plurality of pad protrusion portions are connected to the pad body portion so that they are spaced apart from each other in a circumferential direction of the pad body portion,
the pad through hole is provided as a plurality of pad through holes,
the plurality of pad through holes are formed on the lower surface of the holder body so that they are spaced apart from each other in a circumferential direction of the holder body, and
the substrate processing sweeper has an upper portion connected to the lower surface of the holder body between the pad through holes in the circumferential direction of the holder body, and is disposed to be spaced apart from the pad protrusion portion between the pad protrusion portions in the circumferential direction of the pad body portion.

8. The substrate processing brush of claim 7, wherein a sweeper connection portion extended to the accommodation space and connected to an upper portion of the substrate processing sweeper is formed on the lower surface of the holder body between the pad through holes in the circumferential direction of the holder body, and
a sweeper connection hole to which an upper portion of the substrate processing sweeper is inserted and connected is formed in the sweeper connection portion.

9. The substrate processing brush of claim 8, wherein a connection portion insertion hole to which the sweeper connection portion is inserted is formed in the pad body portion between the pad protrusion portions in the circumferential direction of the pad body portion.

10. The substrate processing brush of claim 9, further comprising a pressing member disposed in the accommodation space to bring the pad body portion into close contact with the holder body.

11. The substrate processing brush of claim 10, wherein the pressing member is provided with a connection insertion groove into which the sweeper connection portion passing through the connection portion insertion hole is inserted.

12. The substrate processing brush of claim 10, further comprising a shaft connection member disposed in the accommodation space between the holder cover and the pressing member and connected to a brush rotation shaft passing through an upper surface of the holder cover.

13. A substrate processing brush comprising:
a holder;
a substrate processing pad detachably disposed in the holder, processing the substrate;
a substrate processing sweeper connected to the holder, processing the substrate together with the substrate processing pad; and
a pressing member disposed inside the holder to bring the substrate processing pad into close contact with the holder; and
a shaft connection member disposed inside the holder between an upper surface of the holder and the pressing member and connected to a brush rotation shaft passing through the upper surface of the holder,
wherein the substrate processing pad includes
a pad body portion disposed inside the holder, and
a pad protrusion portion having an upper portion connected to the pad body portion, protruded downward as much as a protruded length from a lower surface of the holder to the outside of the holder by passing through the lower surface of the holder, and
the substrate processing sweeper has an upper portion connected to the lower surface of the holder so that it is to be adjacent to the pad protrusion portion, and is extended downward as much as an extended length smaller than the protruded length from the lower surface of the holder.

14. A substrate processing apparatus comprising:
a processing container in which a processing space is formed;
a support unit supporting and rotating a substrate in the processing space; and
a brush unit including a substrate processing brush that processes the substrate supported by the support unit,
wherein the substrate processing brush includes:
a holder;
a substrate processing pad detachably disposed in the holder, processing the substrate; and
a substrate processing sweeper connected to the holder, processing the substrate together with the substrate processing pad,
a first portion of the substrate processing pad is disposed inside the holder, and a second portion of the substrate processing pad is protruded to the outside of the holder by passing through one surface of the holder, and
the substrate processing sweeper is connected to one surface of the holder so that it is to be adjacent to the second portion of the substrate processing pad protruded to the outside of the holder, and is extended from one surface of the holder.

15. The substrate processing apparatus of claim 14, wherein a protruded length, which is a length at which the second portion of the substrate processing pad is protruded from one surface of the holder to the outside of the holder, is greater than an extended length, which is a length at which the substrate processing sweeper is extended from one surface of the holder.

16. The substrate processing apparatus of claim 15, wherein a difference between the protruded length and the extended length is 0.2 mm to 0.8 mm.

17. The substrate processing apparatus of claim 14, wherein the substrate processing pad includes
a pad body portion disposed inside the holder, and
a pad protrusion portion having an upper portion connected to the pad body portion, protruded downward as much as a protruded length from a lower surface of the holder to the outside of the holder by passing through the lower surface of the holder, and
the substrate processing sweeper has an upper portion connected to the lower surface of the holder so that it is to be adjacent to the pad protrusion portion, and is extended downward as much as an extended length smaller than the protruded length from the lower surface of the holder.

18. The substrate processing apparatus of claim 17, wherein the holder includes
a holder body in which the pad body portion is disposed and an accommodation space with an open upper portion is formed, and
a holder cover detachably connected to the holder body to cover the open upper portion of the accommodation space.

19. The substrate processing apparatus of claim 18, wherein a pad through hole, which is communicated with the accommodation space and through which the pad protrusion portion passes, is formed on a lower surface of the holder body.

20. The substrate processing apparatus of claim 19, wherein the pad protrusion portion is provided as a plurality of pad protrusion portions,
the plurality of pad protrusion portions are connected to the pad body portion so that they are spaced apart from each other in a circumferential direction of the pad body portion,
the pad through hole is provided as a plurality of pad through holes,
the plurality of pad through holes are formed on the lower surface of the holder body so that they are spaced apart from each other in a circumferential direction of the holder body, and
the substrate processing sweeper has an upper portion connected to the lower surface of the holder body between the pad through holes in the circumferential direction of the holder body, and is disposed to be spaced apart from the pad protrusion portion between the pad protrusion portions in the circumferential direction of the pad body portion.
